(19) United States
(12) Patent Application Publication
(10) Pub. No.: US 2024/0332184 A1
(43) Pub. Date: Oct. 3, 2024

(54) DIRECT BONDING ON BURIED POWER RAILS

(71) Applicant: Adeia Semiconductor Bonding Technologies, Inc., San Jose, CA (US)

(72) Inventors: Rajesh Katkar, Milpitas (IN); Belgacem Haba, Saratoga, CA (US)

(21) Appl. No.: 18/345,607

(22) Filed: Jun. 30, 2023

Related U.S. Application Data
(60) Provisional application No. 63/456,453, filed on Mar. 31, 2023.

(51) Int. Cl. H01L 23/528; H01L 21/8234; H01L 23/522; H01L 23/535

(52) U.S. Cl. CPC H01L 23/5286; H01L 21/823475; H01L 23/5226; H01L 23/535

(57) ABSTRACT

Integrated circuits and method of making including a plurality of transistors, each of the transistors including a source, a drain, and a channel located between the source and the drain. The integrated circuit also includes a plurality of buried power rails including a plurality of VSS power rails and a plurality of VDD power rails, at least one VSS pad and at least one V_{DD} pad, a plurality of vias electrically connecting the at least one VSS pad to at least two of the plurality of VSS power rails, and a plurality of vias electrically connecting the at least one V_{DD} pad to at least two of the plurality of buried VDD power rails.

### CROSS-REFERENCE TO RELATED APPLICATIONS

This application claims the benefit of U.S. Provisional Application No. 63/456,453, filed Mar. 31, 2023, which is hereby incorporated by reference in its entirety.

### BACKGROUND

### Field

The field relates to integrated circuit dies having buried power rails.

### Description of the Related Art

Conventional integrated circuits are fabricated only using the front side of a semiconductor wafer. In the first portion of fabrication, individual components (e.g., transistors, resistors, capacitors) are formed on the front side. This first, device portion is known as the front-end-of-line (FEOL). After the FEOL is completed, a second portion of the integrated circuit, the back-end-of-line (BEOL) is fabricated on the front side of the wafer over the FEOL. The BEOL comprises a stack of alternating dielectric and metallization layers in which interconnects and vias are formed. The interconnects comprise power lines which bring power to and from the devices and signal lines which are used to get data from the devices. The signal lines may be broadly referred to as the signal distribution network (SDN) and the power lines as the power distribution network (PDN). Also included in the BEOL are pads for bonding the chip to a package or circuit board.

As the electrical components, especially the transistors, have gotten smaller and more numerous per chip, the amount of wiring has increased proportionally, yet the chip size has remained largely constant in size. The size of the transistor device level interconnects has been proportionally decreased, while the number of overall metallization layers have significantly increased to accommodate increased number of chip level interconnects. The interconnect layers are connected to each other and the devices by increasingly smaller vias at each level, especially near the device level.

However, the resistance of the interconnects and the vias increase as the vias get smaller. The result has been an exponential increase in resistance as the interconnects and vias shrink to less than 10 nm. Further, as the number of interconnect layers increase, the total ohmic drop from the top metallization layer to the devices gets progressively worse. This ohmic drop also contributes to the joule heating of the wiring layers, effectively increasing the operating temperature of the chip. This increase in resistance, the consequent ohmic drop and higher chip temperature now overshadows the benefits making the various electrical components smaller.

Accordingly, it would be desirable and useful to provide structures and methods for fabricating integrated circuits to address this problem.

### BRIEF DESCRIPTION OF THE DRAWINGS

Specific implementations will now be described with reference to the following drawings, which are provided by way of example, and not limitation.

FIG. 1 is a cross-sectional diagram of a prior art integrated circuit.

FIG. 2A is a cross-sectional diagram of an integrated circuit with buried power rails.

FIG. 2B is a top view of the integrated circuit illustrated in FIG. 2A.

FIG. 3A is a cross-sectional diagram of an integrated circuit according to some embodiments of the disclosed technology.

FIG. 3B is a top view of the integrated circuit illustrated in FIG. 2A.

FIG. 4A is a cross-sectional diagram of an integrated circuit according to some embodiments of the disclosed technology.

FIG. 4B is a top view of the integrated circuit illustrated in FIG. 2A.

FIG. 4C is a cross-sectional diagram of a variation of the integrated circuit illustrated in FIGS. 4A and 4B.

FIG. 4D is cross-sectional diagram of another variation of the integrated circuit illustrated in FIGS. 4A and 4B.

FIGS. 5A-5H are cross-sectional diagrams illustrating a method of making integrated circuit according to some embodiments of the disclosed technology.

FIG. 6 is a cross-sectional diagram of an integrated circuit that is hybrid bonded to a power distribution die.

FIG. 7 is a process flow diagram illustrating a method of making example integrated circuits according to some embodiments of the disclosed technology.

FIG. 8 is a process flow diagram illustrating another method of making example integrated circuits according to some embodiments of the disclosed technology.

FIG. 9A-9B schematically illustrate a process for forming a directly hybrid bonded structure without an intervening adhesive according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The following description refers to integrated circuits. Specifically, the following description refers to integrated circuits with buried power lines and to integrated circuits configured to have a power distribution network located on the back side of the wafer.

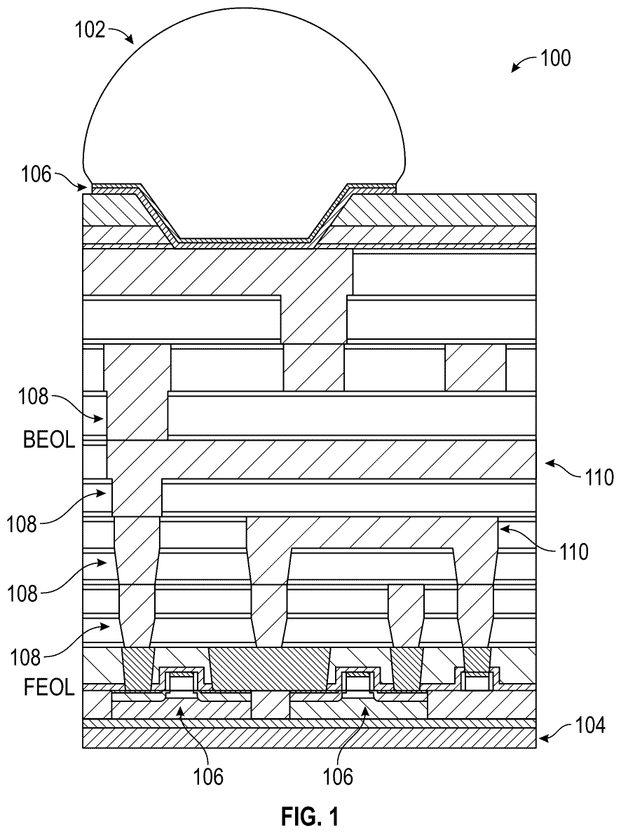

FIG. 1 illustrates a conventional integrated circuit 100. The integrated circuit is fabricated on the front side a substrate 104. In a first portion of fabrication, individual electrical components 106 (e.g., transistors, resistors, capacitors) are formed. This first, device portion is known as the front-end-of-line (FEOL). After the FEOL is completed, a second portion of the integrated circuit, the back-end-of-line (BEOL), is fabricated on over the FEOL. The BEOL comprises a stack of alternating dielectric and metallization layers in which interconnects 110 (wiring connecting electrical components) and vias 108 are formed. The interconnects 110 comprise power lines which bring power to the and from the devices and signal lines which are used to get data from the devices. The signal lines may be broadly referred to as a signal distribution network (SDN) and the power lines as a power distribution network (PDN). Also included in the BEOL are contact pads 152 for bonding the chip to a package or circuit board. The integrated circuit 100 may also include a solder bump 102 which allows for attachment of the integrated circuit 100 to a circuit board or to another integrated circuit 100.

Various embodiments disclosed herein relate to directly bonded structures, such as integrated circuits 100, in which two or more elements can be directly bonded to one another without an intervening adhesive. In some embodiments, direct bonding can involve bonding of a single material on one element and a single material on the other element, where the single materials on the different elements may or may not be the same. Direct bonding can also involve bonding of multiple materials on one element to multiple materials on the other element (e.g., hybrid bonding).

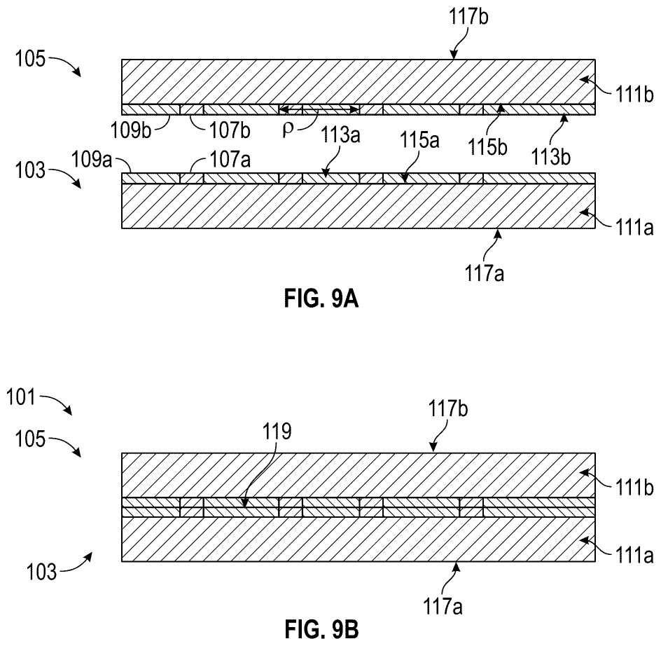

FIGS. 9A and 9B schematically illustrate a process for forming a directly hybrid bonded structure (which may sometimes be referred to as a “direct hybrid bonded structure”) without an intervening adhesive according to some embodiments. As used herein, the term “hybrid bonding” refers to a species of direct bonding in which there are both i) nonconductive features directly bonded to nonconductive features, and ii) conductive features directly bonded to conductive features. In FIGS. 9A and 9B, a bonded structure 101 comprises two elements 103 and 105 that can be directly bonded to one another at a bond interface 119 without an intervening adhesive. Two or more microelectronic elements 103 and 105 (such as semiconductor elements, including, for example, integrated device dies, wafers, passive devices, individual active devices such as power switches, etc.) may be stacked on or bonded to one another to form the bonded structure 101. Conductive features 107a (e.g., contact pads, exposed ends of vias (e.g., TSVs), or a through substrate electrodes) of a first element 103 may be electrically connected to corresponding conductive features 107b of a second element 105. Any suitable number of elements can be stacked in the bonded structure 101. For example, a third element (not shown) can be stacked on the second element 105, a fourth element (not shown) can be stacked on the third element, and so forth. Additionally or alternatively, one or more additional elements (not shown) can be stacked laterally adjacent one another along the first element 103. In some embodiments, the laterally stacked additional element may be smaller than the second element. In some embodiments, the laterally stacked additional element may be two times smaller than the second element.

In some embodiments, the elements 103 and 105 are directly bonded to one another without an adhesive. In various embodiments, a non-conductive field region that includes a non-conductive or dielectric material can serve as a first bonding layer 109a of the first element 103 which can be directly bonded to a corresponding non-conductive field region that includes a non-conductive or dielectric material serving as a second bonding layer 109b of the second element 105 without an adhesive. The non-conductive bonding layers 109a and 109b can be disposed on respective front sides 115a and 115b of device portions 111a and 111b, such as a semiconductor (e.g., silicon) portion of the elements 103, 105. Active devices and/or circuitry can be patterned and/or otherwise disposed in or on the device portions 111a and 111b. Active devices and/or circuitry can be disposed at or near the front sides 115a and 115b of the device portions 111a and 111b, and/or at or near opposite backsides 117a and 117b of the device portions 111a and 111b. Bonding layers can be provided on front sides and/or back sides of the elements. The non-conductive material can be referred to as a non-conductive bonding region, direct bonding layer or bonding layer 109a of the first element 103. In some embodiments, the non-conductive bonding layer 109a of the first element 103 can be directly bonded to the corresponding non-conductive bonding layer 109b of the second element 105 using dielectric-to-dielectric bonding techniques. For example, non-conductive or dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes. It should be appreciated that in various embodiments, the bonding layers 109a and/or 109b can comprise a non-conductive material such as a dielectric material, such as silicon oxide, or an undoped semiconductor material, such as silicon. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials do not comprise polymer materials, such as epoxy, resin or molding materials.

In some embodiments, the device portions 111a and 111b can have a significantly different coefficients of thermal expansion (CTEs) defining a heterogenous structure. The CTE difference between the device portions 111a and 111b, and particularly between bulk semiconductor, typically single crystal portions of the device portions 111a, 111b, can be greater than 5 ppm or greater than 10 ppm. For example, the CTE difference between the bulk substrate can be in a range of 5 ppm to 101 ppm, 5 ppm to 40 ppm, 10 ppm to 101 ppm, or 2 ppm to 20 ppm. In some embodiments, one of the bulk substrate can comprise optoelectronic single crystal materials, including perovskite materials, that are useful for optical piezoelectric or pyroelectric applications, and the other of the bulk substrate 111a, 111b comprises a more conventional substrate material. For example, one of the device portions 111a, 111b comprises lithium tantalate (LiTaO3) or lithium niobate (LiNbO3), and the other one of the device portions 111a, 111b comprises silicon (Si), quartz, fused silica glass, sapphire, or a glass. In other embodiments, one of the device portions 111a and 111b comprises a III-V single semiconductor material, such as gallium arsenide (GaAs), Indium gallium arsenide (InGaAs) or gallium nitride (GaN), and the other one of the device portions 111a and 111b can comprise a non-III-V semiconductor material, such as silicon (Si), or can comprise other materials with similar CTE, such as quartz, fused silica glass, sapphire, or a glass.

In various embodiments, direct hybrid bonds can be formed without an intervening adhesive. For example, nonconductive bonding surfaces 113a and 113b can be polished to a high degree of smoothness. The nonconductive bonding surfaces 113a and 113b can be polished using, for example, chemical mechanical polishing (CMP). The roughness of the polished bonding surfaces 113a and 113b can be less than 30 Å rms. For example, the roughness of the bonding surfaces 113a and 113b can be in a range of about 0.1 Å rms to 15 Å rms, 0.5 Å rms to 10 Å rms, or 1 Å rms to 5 Å rms. The bonding surfaces 113a and 113b can be cleaned and exposed to a plasma and/or etchants to activate the surfaces 113a and 113b. In some embodiments, the surfaces 113a and 113b can be terminated with a species after activation or during activation (e.g., during the plasma and/or etch processes). Without being limited by theory, in some embodiments, the activation process can be performed to break chemical bonds at the bonding surfaces 113a and 113b, and the termination process can provide additional chemical species at the bonding surfaces 113a and 113b that improves the bonding energy during direct bonding. In some embodiments, the activation and termination are provided in the same step, e.g., a plasma to activate and terminate the surfaces 113a and 113b. In other embodiments, the bonding surfaces 113a and 113b can be terminated in a separate treatment to provide the additional species for direct bonding. In various embodiments, the terminating species can comprise nitrogen. For example, in some embodiments, the bonding surface(s) 113a, 113b can be exposed to a nitrogen-containing plasma. Further, in some embodiments, the bonding surfaces 113a and 113b can be exposed to fluorine. For example, there may be one or multiple fluorine peaks at or near a bond interface 119 between the first and second elements 103, 105. Thus, in the directly bonded structure 101, the bond interface 119 between two non-conductive materials (e.g., the bonding layers 109a and 109b) can comprise a very smooth interface with higher nitrogen content and/or fluorine peaks at the bond interface 119. Additional examples of activation and/or termination treatments may be found throughout U.S. Pat. Nos. 9,564,414; 9,391,143; and 10,434,749, the entire contents of each of which are incorporated by reference herein in their entirety and for all purposes. The roughness of the polished bonding surfaces 113a and 113b can be slightly rougher (e.g., about 1 Å rms to 30 Å rms, 3 Å rms to 20 Å rms, or possibly rougher) after an activation process.

In various embodiments, conductive features 107a of the first element 103 can also be directly bonded to corresponding conductive features 107b of the second element 105 without an adhesive (e.g., without solder or other conductive adhesive intervening between the conductive features 107a, 107b). For example, a direct hybrid bonding technique can be used to provide conductor-to-conductor direct bonds along the bond interface 119 that includes covalently direct bonded non-conductive-to-non-conductive (e.g., dielectric-to-dielectric) surfaces, prepared as described above. In various embodiments, the conductor-to-conductor (e.g., conductive feature 107a to conductive feature 107b) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes. In direct hybrid bonding embodiments described herein, conductive features are provided within non-conductive bonding layers, and both conductive and nonconductive features are prepared for direct bonding, such as by the planarization, activation and/or termination treatments described above. Thus, the bonding surface prepared for direct bonding includes both conductive and non-conductive features.

For example, non-conductive (e.g., dielectric) bonding surfaces 113a, 113b (for example, inorganic dielectric surfaces) can be prepared and directly bonded to one another without an intervening adhesive as explained above. Conductive contact features (e.g., conductive features 107a and 107b which may be at least partially surrounded by non-conductive dielectric field regions within the bonding layers 109a, 109b) may also directly bond to one another without an intervening adhesive. In various embodiments, the conductive features 107a, 107b can comprise discrete pads or traces at least partially embedded in the non-conductive field regions. In some embodiments, the conductive contact features can comprise exposed contact surfaces of through substrate vias (e.g., through silicon vias (TSVs)). In some embodiments, the respective conductive features 107a and 107b can be recessed below exterior (e.g., upper) surfaces (non-conductive bonding surfaces 113a and 113b) of the dielectric field region or non-conductive bonding layers 109a and 109b, for example, recessed by less than 30 nm, less than 20 nm, less than 15 nm, or less than 10 nm, for example, recessed in a range of 2 nm to 20 nm, or in a range of 4 nm to 10 nm. The recess can be at or near the middle or center of the cavity in which the conductive features 107a, 107b are disposed, and, additionally or alternatively, can extend or be disposed along sides of the cavity in which the conductive features 107a, 107b are disposed. In various embodiments, prior to direct bonding, the recesses in the opposing elements can be sized such that the total gap between opposing contact pads 152 is less than 15 nm, or less than 10 nm. The non-conductive bonding layers 109a and 109b can be directly bonded to one another without an adhesive at room temperature in some embodiments and, subsequently, the bonded structure 101 can be annealed. Upon annealing, the conductive features 107a and 107b can expand and contact one another to form a metal-to-metal direct bond. Beneficially, the use of Direct Bond Interconnect, or DBI®, techniques commercially available from Adeia of San Jose, CA, can enable high density of conductive features 107a and 107b to be connected across the direct bond interface 119 (e.g., small or fine pitches for regular arrays). In some embodiments, the pitch of the conductive features 107a and 107b, such as conductive traces embedded in the bonding surface of one of the bonded elements, may be less than 101 microns or less than 10 microns or even less than 2 microns. For some applications, the ratio of the pitch of the conductive features 107a and 107b to one of the dimensions (e.g., a diameter) of the bonding pad is less than is less than 20, or less than 10, or less than 5, or less than 3 and sometimes desirably less than 2. In other applications, the width of the conductive traces embedded in the bonding surface of one of the bonded elements may range between 0.3 microns to 20 microns, e.g., in a range of 0.3 microns to 3 microns. In various embodiments, the conductive features 107a and 107b and/or traces can comprise copper, nickel, gold, indium, silver or their alloys, although other metals may be suitable. For example, the conductive features disclosed herein, such as the conductive features 107a and 107b, can comprise fine-grain metal (e.g., a fine-grain copper).

Thus, in direct bonding processes, a first element 103 can be directly bonded to a second element 105 without an intervening adhesive. In some arrangements, the first element 103 can comprise a singulated element, such as a singulated integrated device die. In other arrangements, the first element 103 can comprise a carrier or substrate (e.g., a wafer) that includes a plurality (e.g., tens, hundreds, or more) of device regions that, when singulated, form a plurality of integrated device dies. In some embodiments, the first element may comprise of a package or singulated package. Similarly, the second element 105 can comprise a singulated element, such as a singulated integrated device die. In other arrangements, the second element 105 can comprise a carrier or substrate (e.g., a wafer) or a package. The embodiments disclosed herein can accordingly apply to wafer-to-wafer (W2W), die-to-die (D2D), or die-to-wafer (D2W) package to wafer (P2W), package to package, die to flat panel, package to flat panel bonding processes. In wafer-to-wafer (W2W) processes, two or more wafers can be directly bonded to one another (e.g., direct hybrid bonded) and singulated using a suitable singulation process. After singulation, side edges of the singulated structure (e.g., the side edges of the two bonded elements) may be substantially flush and may include markings indicative of the common singulation process for the bonded structure (e.g., saw markings if a saw singulation process is used).

As explained herein, the first and second elements 103 and 105 can be directly bonded to one another without an adhesive, which is different from a deposition process and results in a structurally different interface compared to a deposition. In one application, a width of the first element 103 in the bonded structure is similar to a width of the second element 105. In some other embodiments, a width of the first element 103 in the bonded structure 101 is different from a width of the second element 105. Similarly, the width or area of the larger element in the bonded structure may be at least 10% larger than the width or area of the smaller element. The first and second elements 103 and 105 can accordingly comprise non-deposited elements. Further, directly bonded structures 101, unlike deposited layers, can include a defect region along the bond interface 119 in which nanometer-scale voids (nanovoids) are present. The nanovoids may be formed due to activation of the bonding surfaces 113a and 113b (e.g., exposure to a plasma). As explained above, the bond interface 119 can include concentration of materials from the activation and/or last chemical treatment processes. For example, in embodiments that utilize a nitrogen plasma for activation, a nitrogen peak can be formed at the bond interface 119. The nitrogen peak can be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In embodiments that utilize an oxygen plasma for activation, an oxygen peak can be formed at the bond interface 119. In some embodiments, the bond interface 119 can comprise silicon oxynitride, silicon oxycarbonitride, or silicon carbonitride. As explained herein, the direct bond can comprise a covalent bond, which is stronger than van Der Waals bonds. The bonding layers 109a and 109b can also comprise polished surfaces that are planarized to a high degree of smoothness.

In various embodiments, the metal-to-metal bonds between the conductive features 107a and 107b can be joined such that metal grains grow into each other across the bond interface 119. In some embodiments, the metal is or includes copper, which can have grains oriented along the 111 crystal plane for improved copper diffusion across the bond interface 119. In some embodiments, the conductive features 107a and 107b may include nanotwinned copper grain structure, which can aid in merging the conductive features during anneal. The bond interface 119 can extend substantially entirely to at least a portion of the bonded conductive features 107a and 107b, such that there is substantially no gap between the non-conductive bonding layers 109a and 109b at or near the bonded conductive features 107a and 107b. In some embodiments, a barrier layer may be provided under and/or laterally surrounding the conductive features 107a and 107b (e.g., which may include copper). In other embodiments, however, there may be no barrier layer under the conductive features 107a and 107b, for example, as described in U.S. Pat. No. 11,195,748, which is incorporated by reference herein in its entirety and for all purposes.

Beneficially, the use of the hybrid bonding techniques described herein can enable extremely fine pitch between adjacent conductive features 107a and 107b, and/or small pad sizes. For example, in various embodiments, the pitch p (i.e., the distance from edge-to-edge or center-to-center, as shown in FIG. 9A) between adjacent conductive features 107a (or 107b) can be in a range of 0.5 microns to 50 microns, in a range of 0.75 microns to 25 microns, in a range of 1 micron to 25 microns, in a range of 1 micron to 10 microns, or in a range of 1 micron to 5 microns. Further, a major lateral dimension (e.g., a pad diameter) can be small as well, e.g., in a range of 0.25 microns to 30 microns, in a range of 0.25 microns to 5 microns, or in a range of 0.5 microns to 5 microns.

As described above, the non-conductive bonding layers 109a, 109b can be directly bonded to one another without an adhesive and, subsequently, the bonded structure 101 can be annealed. Upon annealing, the conductive features 107a, 107b can expand and contact one another to form a metal-to-metal direct bond. In some embodiments, the materials of the conductive features 107a, 107b can interdiffuse during the annealing process.

As discussed above and illustrated in FIG. 1, in conventional integrated circuits 100, the electrical components 106 (e.g., transistors or other devices), the signal distribution network and the power distribution network (vias 108—vertically oriented electrical connections and interconnects 110—horizontally oriented electrical connections, also known as traces) are all fabricated on the frontside of a substrate 104. Typically, the solder bump 102 is provided which allows for flip chip attachment of the integrated circuit 100 to a circuit board. In some integrated circuits, wire bond pads may be provided in place of the solder bumps 102. As discussed above, as the transistors have gotten smaller and more numerous per chip, the amount of wiring has increased. However, the real estate to accommodate the extra wiring (signal, power and ground) has not increased because the size of the chip has remained essentially constant. The solution has to this problem has been to provide additional layers to the BEOL for the extra wiring. However, the use of thinner wires and additional layers has resulted increased wring length, which leads to in increased resistance and an increased ohmic drop.

An alternative solution to adding more layers to the BEOL is to use buried power rails—power rails located inside the semiconductor substrate rather than on a metal layer above the substrate. However, earlier attempts to use buried power rails, often decreased device performance due to stress, degradation and metal contamination from the fabrication process. It has also been difficult to land the nano-vias on the buried power rails to due the small size of the buried power rails and its close proximity of VDD and/or VSS. Further, forming nano through-substrate vias (TSV) is challenging due to space constraints as well as stresses that may be induced on the conduction channels between fins.

In contrast, in embodiments of the present disclosure as discussed in more detail below, buried power rails can be fabricated in the FEOL on the back side of the substrate 104 extending below the electrical components 106 into the substrate 104. Further, the signal distribution and the power distribution networks are separately located in regards to the front side and the back side of the substrate 104, respectively. That is, in various embodiments, the signal distribution network may be fabricated in the BEOL on the front side of the substrate 104, while the power distribution network (including connections to power and ground) may be fabricated in a separate die which may then be attached to the back side of the substrate 104 by a hybrid direct bonding process. In another embodiment, the signal distribution network may be fabricated in the BEOL on the front side of the substrate 104, while the power distribution network (including connections to power and ground) may be fabricated on the backside of the wafer after thinning the wafer and exposing the buried power rails in another BEOL process performed on the back side of the thinned substrate. In alternative embodiments, the power distribution network may fabricated in the BEOL while the signal distribution network may be fabricated in a separate die which may then be attached to the back side of the substrate 104 by a hybrid direct bonding process

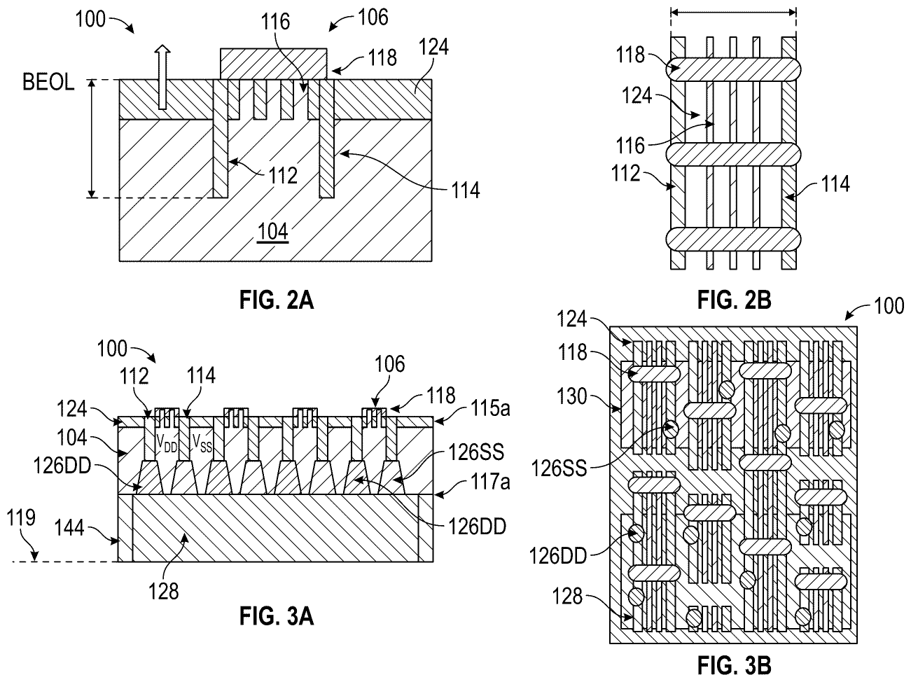

FIGS. 2A and 2B are exemplary cross-sectional and top views, respectively, of the portion of an integrated circuit 100 with buried power rails. As illustrated the integrated circuit 100 includes first and second buried power rails, e.g., VDD buried power rails 112 and VSS buried power rails 114 which are configured to provide power and ground or reference voltage, respectively, to the electrical components 106. The illustrated electrical component 106 can comprise a transistor (e.g., a FinFET transistor with a plurality of (e.g., three) fins 116) and gate electrodes 118. However, the electrical component 106 may be any suitable passive or active electrical component. As illustrated, the VDD buried power rails 112, VSS buried power rails 114 and electrical components 106 are fabricated on the front side of the die or wafer in the FEOL, with the power rails 112, 114 extending into the substrate 104 below the electrical components 106. The VDD buried power rails 112 and VSS buried power rails 114 extend from a dielectric layer (e.g., a shallow trench isolation layer (STI) 124) into the substrate 104. The shallow trench isolation layer can comprise any suitable type of insulating material, such as silicon oxide. In embodiments, stress transfer to the conduction channel may be minimized by burying tungsten buried power rails below the fins of the FinFETs, deep into the shallow trench isolation. Note, the various embodiments are not limited to FinFETs. In alternative embodiments other node technologies may be used, such as gate all around (GAA) including nano sheet and nanowire configurations. In embodiments, in which nodes are greater than 2 nm, the pitch between neighboring buried rails VDD and VSS may be only few tens of nm, for example about 20-100 nm or less. Although only one power rail VDD is described indicating one voltage line, 2 or more such power lines providing 2 or more voltages to different parts of the chip may also be provided, e.g. VDD1, VDD2, VDD3, etc.

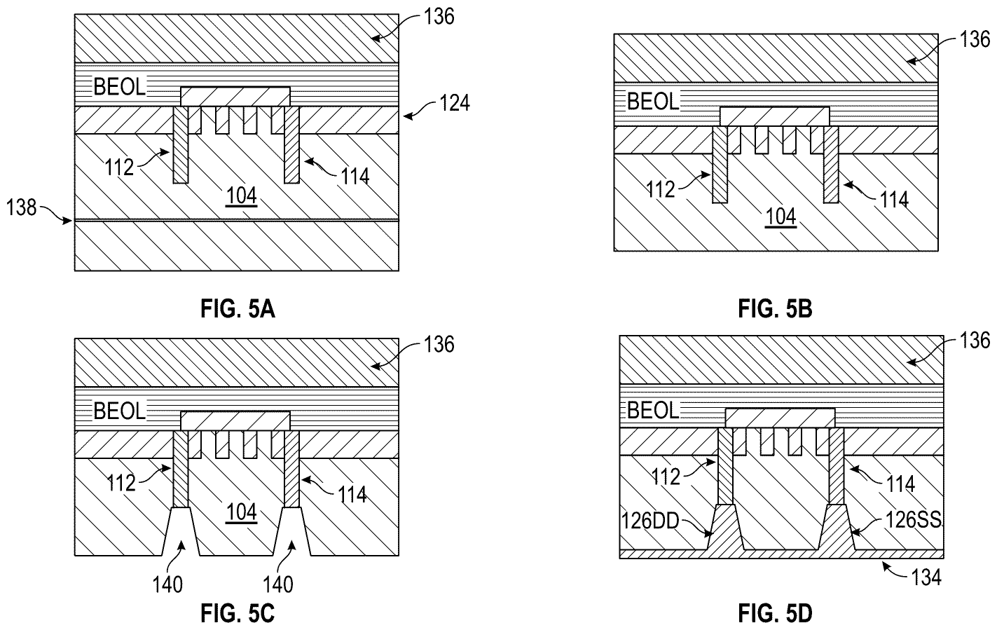

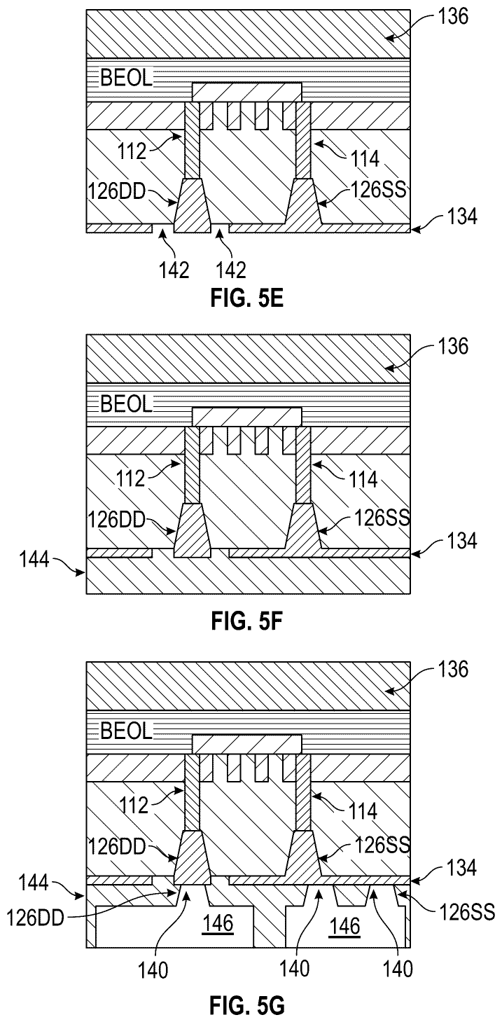

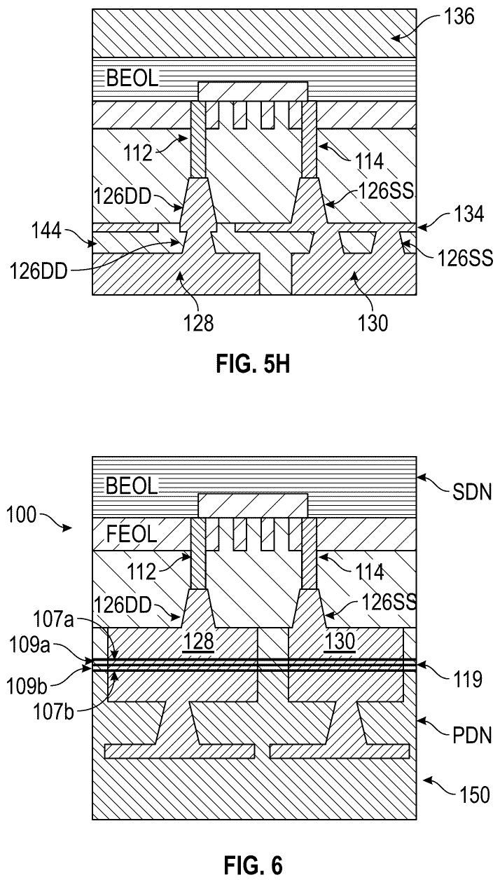

FIGS. 3A and 3B are schematic cross-sectional and top views, respectively, of an integrated circuit 100 according to an embodiment. As illustrated, first and second bond pads (e.g., VDD bond pads 128 and VSS bond pads 130) are formed in the back side 117a of the substrate 104, while the electrical components 106 are formed on the active, front side 115a of the substrate 104. In an embodiment, a dielectric layer 144 is formed on the back side 117a of the substrate 104 and the VDD bond pads 128 and VSS bond pads 130 are formed in the dielectric layer 144. As further illustrated, VDD bond pads 128 and VSS bond pads 130 are laterally separated on the back side of the substrate 104 and are electrically isolated from each other. VDD bond pads 128 and VSS bond pads 130 are electrically isolated from each other with a dielectric layer as illustrated in FIGS. 5A-5G and discussed in more detail below in regards to FIGS. 5A-5G. VDD bond pads 128 and VSS bond pads 130 each extend over the sources and drains of multiple transistor cells and are connected to the sources and drains by respective VDD vias 126DD and VSS vias 126SS. In this embodiment, each of the VDD bond pads 128 and VSS bond pads 130 are electrically connected to at least two respective VDD buried power rails 112 or VSS buried power rails 114.

Further, each of the VDD bond pads 128 and VSS bond pads 130 are electrically connected to at least two transistor cells, where a transistor cell or unit cell may serve as a fundamental functional block, circuit block or transistor layout of the chip. For example, transistor or unit cells may include, but are not limited to, memory cells, logic cells, combinational cells, etc. As a further example, a transistor or unit cell may be a 6T SRAM cell with 6 transistors. In embodiments, several transistors in a unit cell or transistor layout can share VDD and VSS buried power rails 112, 114 using 1 or 2 (or a few) VDD or VSS vias 126DD, 126SS connecting eventually (e.g., via routing/RDL layers) to VSS or VDD bond pads 128, 130. In embodiments, one cell fabricated using, for example, 5 nm technology may have a footprint of several 10s or 100s of nanometers, thereby relaxing the pitch of the of the conductive features 107a and 107b from ˜5 nm at the transistor to 10s-100s of nanometers at the direct bonding level. In embodiments, several such unit cells may share VDD and VSS buried power rails 112. 114. which may further help broaden the minimum pitch at the direct bonding level. In addition, several VDD/VSS buried power rails 112, 114 from several unit cells may be connected using a limited number of vias to 1 or 2 VSS or VDD bond pads 128, 130.

In various embodiments, the VDD bond pads 128 and VSS bond pads 130 may be electrically connected to respective VDD buried power rails 112 and VSS buried power rails 114 with a plurality of respective VDD vias 126DD and VSS vias 126SS. Further, in various embodiments, each of the VDD buried power rails 112 and VSS buried power rails 114 may provide power and/or ground to a plurality of transistor cells in the integrated circuit 100.

In an embodiment, the power distribution network, conventionally located in the BEOL may be fabricated in a separate chip (not shown), e.g., a power distribution chip. In an embodiment, the power distribution chip may have bond pads configured to directly bond to corresponding VDD bond pads 128 and VSS bond pads 130 of the integrated circuit 100. In this embodiment, the power distribution chip may be hybrid bonded along bond interface 119 (as discussed in regards to FIGS. 9A-9B) to the back side of the integrated circuit 100, thereby providing a back side power distribution network to the integrated circuit 100 Advantageously in this embodiment, the hybrid bonded VDD bond pads 128 and VSS bond pads 130 may be connected to separate VDD and VSS buried power rails 112, 114 and transistor cells with one or more back side vias 126DD, 126SS. The use of multiple back side vias 126DD, 126SS to connect to the VDD and VSS buried power rails 112, 114 and transistor cells reduces the resistance. Additionally, the VDD bond pads 128 and VSS bond pads 130 and the VDD back side vias and the VSS back side vias may be formed at the same time using a dual damascene process, thereby saving several process steps. Additionally, the VDD bond pads 128 and VSS bond pads 130 may be elongated, having a length to width ratio of 1:1 to 10:1, such as greater than 2:1, greater than 4:1, greater than 5:1, etc. The elongated VDD bond pads 128 and VSS bond pads 130 facilitates alignment in the hybrid bonding process. Further advantageously, the use of multiple vias to connect to larger bond pads essentially enables an efficient fan-out from the very small pitch vias to the relatively larger pitch pads. Thus, it is relatively easy go from a fine pitch to a large pitch. Further, some embodiments discussed in more detail below, provide shielding of the conduction channels from interference due to the use of comparatively large, VDD bond pads 128 and VSS bond pads 130 formed very close to the conduction channels.

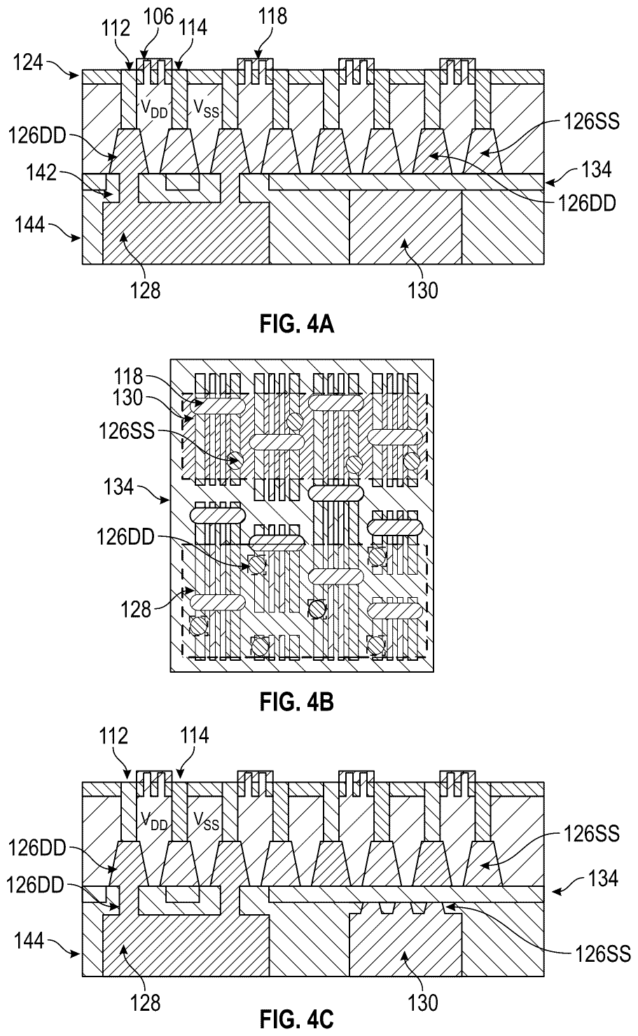

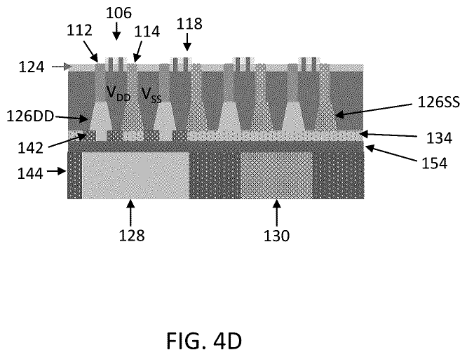

FIGS. 4A and 4B are cross-sectional and top views, respectively, of an integrated circuit according to another embodiment. In this embodiment, a VSS ground plane or reference plane 134 may be formed between the VDD and VSS bond pads 128, 130 and the conduction channels or VDD and VSS vias 126DD, 126SS such that the VSS buried power rails 114 are grounded to the VSS ground plane or reference plane 134 through the VSS vias 126SS. Similar to the previous embodiment, the VDD bond pads 128 and VSS bond pads 130 may be formed in a dielectric layer 144 formed on the back side 117a of the substate 104. As illustrated, openings 142 may be formed in the VSS ground plane or reference plane 134 such that the VDD vias 126DD connect with the VDD bond pads 128 without being shorted to ground. In various embodiments, the reference plane 134 may be located 100 nm to 3 microns below the VDD buried power rails 112 and VSS buried power rails 114. Further, as illustrated in FIGS. 4A and 4B, the length, width and height or thickness of the VDD bond pads 128 and VSS bond pads 130 may be different from each other. In particular, the VSS bond pads 130 may be narrower than the VDD bond pads 128, yet have a similar cross-sectional area because the height of the VSS bond pads 130 is larger. The VSS bond pads 130 can be made smaller because the VSS ground plane can be made large. Also, the VSS bond pads 130 can be made smaller because the VSS bond pads 130 extend deeper into the dielectric layer 144. In various embodiments, the vertical separation between the VDD buried power rails 112 and VSS buried power rails 114 and the VDD bond pads 128 and the VSS bond pads 130 may be 100 nm to 3 microns.

FIG. 4C is a cross-sectional diagram of a variation of the integrated circuit illustrated in FIGS. 4A and 4B. In this embodiment, VSS bond pads 130 are connected to the VSS ground plane or reference plane 134 with VSS back side vias 126SS. In embodiments, the gap between conduction channels and ground plane or reference plane 134 may be in the range between 50-500 nm, such as greater than 100 nm, greater than 200 nm, such as greater than 300 nm.

FIG. 4D is a cross-sectional diagram of another variation of the integrated circuit illustrated in FIGS. 4A and 4B. In this embodiment, the integrated circuit includes at least one redistribution layer (RDL) 154 located between the electronic components 106 or VDD, VSS buried power rails 112, 114 and the VDD or VSS bond pads 128. 130. A redistribution layer is a patterned metal layer in a dielectric layer, which redistributes the input/output (I/O) of the integrated circuit 100 to a different lateral location. The new lateral location can be laterally outward or inward. RDL technology enables placement of the dies in a compact and efficient way, thereby reducing the overall footprint of the device. As illustrated, the RDL 154 is located below the reference plane 134, that is. between the reference plane 134 and the VDD bond pads 128 and VSS bond pads 130. Alternatively. the RDL 154 may be located above the reference plane 134. that is. between the reference plane 134 and the electronic components 106 or VDD, VSS buried power rails 112, 114. In some embodiments, the metallization in the reference plane 134 may also be used for some routing or for redistribution. In another embodiment, one or more redistribution layers 154 may be added below the VSS and VDD bond pads 128. 130 to allow for the pitch to expand from narrower transistor cells or VDD, VSS buried power rails 112, 114 to the broader pitch of VSS and VDD bond pads 128, 130.

FIGS. 5A-5H are cross-sectional diagrams illustrating a method of making integrated circuit according to some embodiments. As illustrated in FIG. 5A, an in-process integrated circuit is provided. The in-process integrated circuit includes VDD buried power rails 112 and VSS buried power rails 114. Also included is an etch stop layer 138 in the wafer 104. In this step, the in-process integrated circuit is attached to a front side carrier 136. In some embodiments, the in-process integrated circuit can be directly bonded to the front side carrier 136 without an adhesive. In other embodiments, the in-process integrated circuit can be directly bonded to the front side carrier 136 using any other temporary bonding material suitable for backside grinding, thinning and backside BEOL formation processes.

Referring to FIG. 5B, the wafer 104 is thinned. Thinning may be performed by a combination of grinding, polishing, wet etching or dry etching. The wafer 104 is thinned until the etch stop layer 138 is reached. The etch stop layer 138 may then be removed with another etching step. In an embodiment, the wafer 104 comprises Si and the etch stop layer 138 may comprise silicon oxide, silicon nitride, SiGe, etc. or any other suitable embedded etch stop layer. Other combinations of wafer and etch stop layer materials may be used.

Referring to FIG. 5C, via holes 140 may be formed in the back side of the wafer 104 extending to the VDD buried power rails 112 and the VSS buried power rails 114. In an embodiment, the via holes 140 may be formed by etching, such as by wet etching or dry etching.

Referring to FIG. 5D, a conductive material may be deposited (e.g., by electroplating, chemical vapor deposition (CVD), physical vapor deposition (PVD), atomic layer deposition (ALD), or any other suitable process) in the via holes 140 to form VDD vias 126DD, VSS vias 126SS and VSS ground plane or reference plane 134. The conductive material may be a metal or a silicide. The VSS ground plane or reference plane 134 may then be polished and planarized. Planarization may be performed by chemical-mechanical polishing or by any other suitable method.

Referring to FIG. 5E, VSS ground plane or reference plane 134 may be patterned and openings 142 may be formed in the VSS ground plane or reference plane 134 so that subsequently formed VDD buried power rails are not grounded to the VSS ground plane or reference plane 134.

Referring to FIG. 5F, one or more dielectric layers 144 may be deposited over the back surface of the in-process integrated circuit. The one or more dielectric layer 144 may be made of any suitable materials such as SiO2 or silicon nitride.

Referring to FIG. 5G, via holes 140 may be formed through the dielectric layer 144 to the VSS ground plane or reference plane 134 and to the VDD buried power rail 112. Next, trenches 146 may formed in the dielectric layer 144 connecting multiple via holes 140 to the VSS ground plane or reference plane 134 and to the VDD buried power rail 112, respectively.

Referring to FIG. 5H, the via holes 140 and the trenches 146 may be filled with conductive material to form VSS vias 126SS, VDD vias 126DD and the VDD bond pads 128 and the VSS bond pads 130. This manner of forming the VSS vias 126SS, VDD vias 126DD, VDD bond pads 128 and the VSS bond pads 130 may be referred to as a dual damascene process. In an alternative process, the via holes 140 are formed and filled with conducting material to form the VSS vias 126SS and VDD vias 126DD first in a first damascene process. Then the trenches 146 are formed and filled with a conductive material to form the VDD bond pads 128 and the VSS bond pads 130 in a second, separate damascene process.

In an embodiment, a power distribution network may be formed in a separate chip (shown in FIG. 6 and discussed in more detail below) and direct bonded to the in-process integrated circuit shown in FIG. 5H with a direct hybrid bonding process. In this manner, the PDN may be formed on the back side of the integrated circuit while the electrical components and the signal distribution network is formed on the front side of the integrated circuit.

In the various embodiments discussed above, the VDD vias 126DD and VSS vias 126SS may be made of W, Ru, Co or Cu if processing at higher temperatures. In such embodiments, the VDD bond pads 128 and the VSS bond pads 130 may be formed of a different material, such as copper, which may be formed using lower temperature processes when forming the BEOL. If the VDD vias 126DD and VSS vias 126SS are made of Cu, a barrier layer, such as silicon nitride and a linter layer, such as titanium nitride may be first deposited prior to forming the VDD vias 126DD and VSS vias 126SS. In various embodiments, the power line pitch is in a range of 10 nm to 500 nm such as 10 nm to 100 nm, 20 nm to 200 nm or 50 nm to 500 nm. In various embodiments, the device pitch is in a range of 1 nm to 200 nm, such as, 1 nm to 10 nm, 15 nm to 150 nm, 20 nm to 100 nm, or 40 nm to 80 nm. In various embodiments, the thickness of the VDD bond pads 128 and the VSS bond pads 130 can be at least 0.2 micron such as, thickness of 200 nm or 500 nm or 1 micron. The pitch of the of the VDD bond pads 128 and the VSS bond pads 130 may be 0.1 to 1.0 micron with thicknesses from 0.1 to 0.5 microns. In various embodiments, the vertical separation between the buried power line and bottom of the VDD bond pads 128 and the VSS bond pads 130 may be in the range of 200 nm to 5 microns. In various embodiments, the vertical separation between the buried power line and the ground plane or reference plane 134 may be in the range of 100 nm to 3 microns.

FIG. 6 illustrates a cross-sectional view of an embodiment in which a power distribution network PDN may be formed in a separate chip 150 and hybrid bonded to an integrated circuit 100. Although the illustrated integrated circuit 100 corresponds to the embodiment illustrated in FIG. 3A above, any of the embodiment integrated circuits 100 discussed above may have a separate chip 150 with a PDN formed therein hybrid bonded to it.

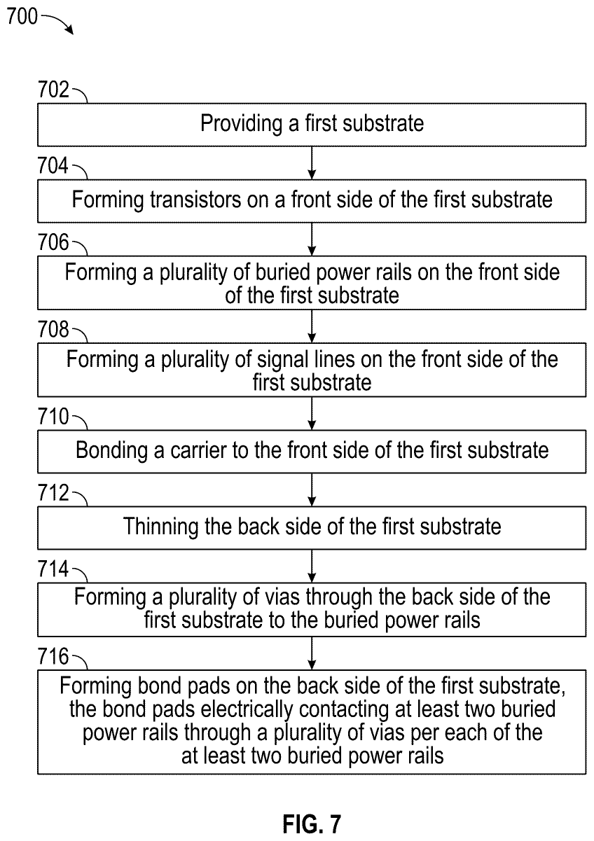

FIG. 7 is a process flow diagram illustrating a method 700 of making example integrated circuits according to some embodiments of the disclosed technology. Referring to step 702, a first substrate is provided. Referring to step 704, transistors are formed on a front side of the first substrate. Referring to step 706, a plurality of buried power rails are formed on the front side of the first substrate. Referring to step 708, a plurality of signal lines are formed on the front side of the first substrate. Referring to step 710, a carrier is bonded to the front side of the first substrate. Referring to step 712, the back side of the first substrate is thinned. Referring to step 714, a plurality of vias is formed through the back side of the first substrate to the buried power rails. Referring to step 716, bond pads are formed on the back side of the first substrate, the bond pads electrically contacting at least two buried power rails through a plurality of vias per each of the at least two buried power rails.

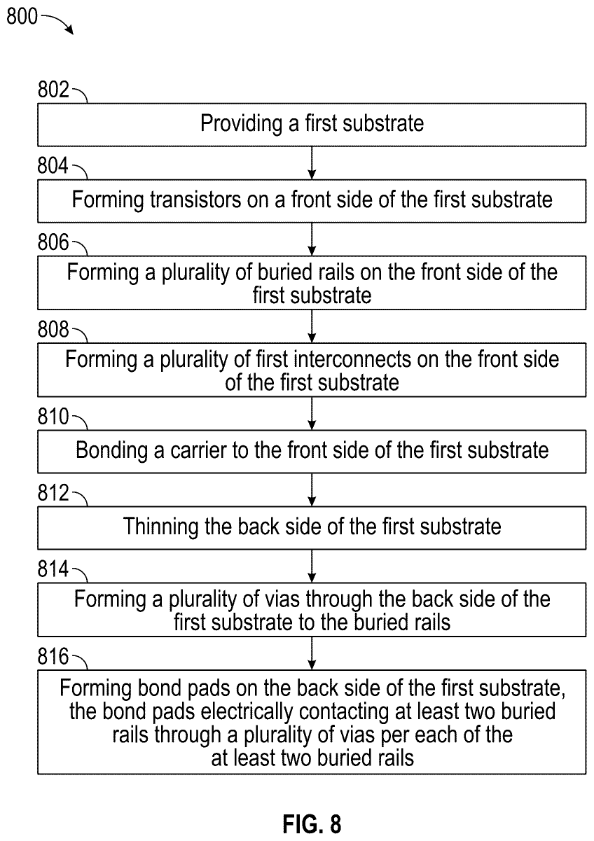

FIG. 8 is a process flow diagram illustrating another method of making example integrated circuits according to some embodiments of the disclosed technology. Referring to step 802, a first substrate is provided. Referring to step 804, transistors are formed on a front side of the first substrate. Referring to step 806, a plurality of buried rails are formed on the front side of the first substrate. Referring to step 808, a plurality of first interconnects are formed on the front side of the first substrate. Referring to step 810, a carrier is bonded to the front side of the first substrate. Referring to step 812, the back side of the first substrate is thinned. Referring to step 814, a plurality of vias is formed through the back side of the first substrate to the buried rails. Referring to step 816, bond pads are formed on the back side of the first substrate, the bond pads electrically contacting at least two buried rails through a plurality of vias per each of the at least two buried rails.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An integrated circuit comprising:
a plurality of transistors located on a first side of a substrate;
a plurality of buried power rails connected to the plurality of transistors, the plurality of buried power rails comprising a plurality of VSS power rails and a plurality of V_{DD} power rails;
at least one VSS pad and at least one V_{DD} pad;
a plurality of vias electrically connecting the at least one VSS pad to at least two of the plurality of VSS power rails, wherein the at least one VSS pad is located on a second side of the substrate opposite of the first side; and
a plurality of vias electrically connecting the at least one VDD pad to at least two of the plurality of buried V_{DD} power rails, wherein the at least one VDD pad is located on a second side of the substrate opposite of the first side.

2. The integrated circuit on claim 1, wherein the plurality VSS and VDD pads are provided on the backside of the die.

3. The integrated circuit on claim 1, wherein the plurality VSS and VDD pads are configured for hybrid bonding.

4. The integrated circuit of claim 1, wherein the plurality of buried VSS power rails or the plurality of VDD buried power rails provide power to the plurality of transistors.

5. The integrated circuit of claim 1, wherein the plurality of buried power rails are located in a front end of the line (FEOL).

6. The integrated circuit of claim 1, wherein the at least one VSS pad and/or the at least one V_{DD} pad has a length to width ratio in the range of 1:1 to 10:1.

7. The integrated circuit of claim 1, wherein the plurality of transistors comprise fin field effect transistors (FinFETs) or gate all around field effect transistors (GAA).

8. The integrated circuit of claim 1, further comprising a ground or reference plane located below the plurality of buried power rails.

9. The integrated circuit of claim 1, wherein at least one VSS pad and the at least one VDD pad are located 100 nm to 3 microns below the plurality of buried power rails.

10. The integrated circuit of claim 8, wherein the ground or reference plane is located 100 nm to 3 microns below the plurality of buried power rails.

11. The integrated circuit of claim 8, wherein at least one of a length, width, and thickness of the at least one VSS pad is different from a length, width, and thickness of the at least one VDD pad.

12. The integrated circuit of claim 8, wherein the plurality of vias comprises VSS vias and VDD vias and all of the VSS vias are shorted to the ground or reference plane.

13. The integrated circuit of claim 8, wherein the ground or reference plane comprises openings allowing the VDD vias to pass through the ground or reference plane without being shorted to the ground or reference plane.

14. The integrated circuit of claim 8, wherein the ground or reference plane is located directly on the at least one VSS pad.

15. The integrated circuit of claim 8, wherein the ground or reference plane is electrically connected to the at least one VSS pad with vias.

16. An integrated circuit comprising:
a plurality of transistors located on a first side of a substrate;
a plurality of buried power rails connected to the plurality of transistors, the plurality of buried power rails comprising a plurality of VSS power rails and a plurality of V_{DD} power rails;
at least one VSS pad and at least one VDD pad located on a second side of the substrate opposite of the first side; and
a power distribution network element hybrid bonded to a hybrid bonding surface including the at least one VSS pad and the at least one VDD pad.

17. The integrated circuit of claim 16 further comprising:
a plurality of vias electrically connecting the at least one VSS pad to at least two of the plurality of VSS power rails; and
a plurality of vias electrically connecting the at least one VDD pad to at least two of the plurality of buried V_{DD} power rails.
